(19) United States
(12) Patent Application Publication
(10) Pub. No.: US 2023/0290698 A1
(43) Pub. Date: Sep. 14, 2023

(54) SEMICONDUCTOR DEVICE

(71) Applicant: KABUSHIKI KAISHA TOSHIBA, Tokyo (JP)

(72) Inventors: Kazuya OHIRA, Nerima (JP); Hideto FURUYAMA, Yokohama (JP)

(73) Assignee: KABUSHIKI KAISHA TOSHIBA, Tokyo (JP)

(21) Appl. No.: 17/896,299

(22) Filed: Aug. 26, 2022

(30) Foreign Application Priority Data
Mar. 10, 2022 (JP) 2022-036875

(51) Int. Cl. H01L 23/12; H01L 23/40; H01L 23/48; H01L 23/528; G02B 6/42

(52) U.S. Cl. CPC H01L 23/12; H01L 23/4006; H01L 23/481; H01L 23/528; G02B 6/4201

(57) ABSTRACT

A semiconductor device includes a holding member including a component placement part; a back plate; a substrate including a mounting surface facing the holding member, and a back surface facing the back plate; a plurality of mounting pads located at the mounting surface; a package component including a terminal placement surface facing the mounting surface; and a plurality of package terminals located at the terminal placement surface. The substrate is held between the holding member and the back plate. The package component is located in the component placement part, and held between the holding member and the substrate. The package terminals are in direct contact with the mounting pads.

### CROSS-REFERENCE TO RELATED APPLICATION

This application is based upon and claims the benefit of priority from Japanese Patent Application No. 2022-036875, filed on Mar. 10, 2022; the entire contents of which are incorporated herein by reference.

### FIELD

Embodiments described herein relate generally to a semiconductor device.

### BACKGROUND

Packages of semiconductor integrated circuits include a LGA (Land Grid Array) package that is mountable to a mounting substrate without solder by using a socket or the like, and is used as a repairable package that is detachable from and re-attachable to the mounting substrate.

### BRIEF DESCRIPTION OF THE DRAWINGS

FIG. 1A is a schematic cross-sectional view of a semiconductor device of a first embodiment; and FIG. 1B is an enlarged schematic cross-sectional view of an electrical connection part between a package component and a mounting substrate;

FIG. 2A is a schematic plan view of the semiconductor device of the first embodiment; and FIG. 2B is a schematic plan view of the semiconductor device of the first embodiment in which a second holding part is removed;

FIG. 3 is a schematic cross-sectional view of a semiconductor device of a second embodiment;

FIG. 4 is a schematic cross-sectional view of a semiconductor device of a third embodiment;

FIG. 5 is a schematic cross-sectional view of a semiconductor device of a fourth embodiment;

FIG. 6 is a schematic cross-sectional view of a semiconductor device of a fifth embodiment; and

FIG. 7 to FIG. 9 are schematic cross-sectional views of a semiconductor device of a sixth embodiment.

### DETAILED DESCRIPTION

According to one embodiment, a semiconductor device includes a holding member including a component placement part; a back plate; a substrate including a mounting surface facing the holding member, and a back surface positioned at a side opposite to the mounting surface, the back surface facing the back plate; a plurality of mounting pads located at the mounting surface; a package component including a terminal placement surface, the terminal placement surface facing the mounting surface; and a plurality of package terminals located at the terminal placement surface. The substrate is held between the holding member and the back plate. The package component is located in the component placement part, and held between the holding member and the substrate. The package terminals are in direct contact with the mounting pads.

Exemplary embodiments will now be described with reference to the drawings.

The drawings are schematic or conceptual; and the relationships between the thickness and width of portions, the proportional coefficients of sizes among portions, etc., are not necessarily the same as the actual values thereof. Furthermore, the dimensions and proportional coefficients may be illustrated differently among drawings, even for identical portions.

In the specification of the application and the drawings, components similar to those described in regard to a drawing thereinabove are marked with like reference numerals, and a detailed description is omitted as appropriate.

### First Embodiment

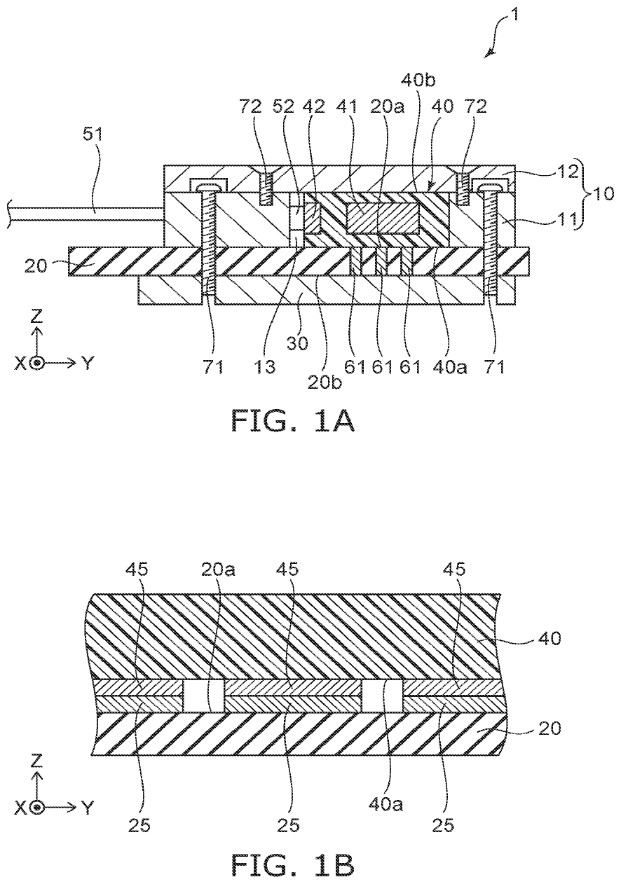

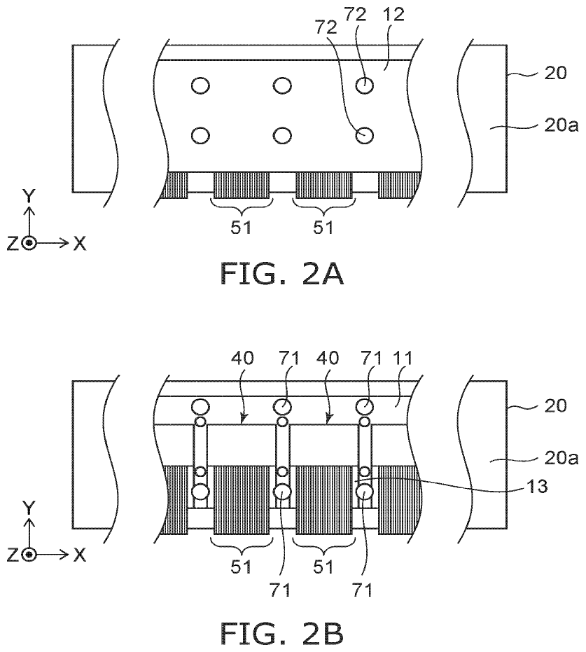

As shown in FIG. 1A, a semiconductor device 1 of a first embodiment includes a holding member 10, a substrate 20, a back plate 30, and a package component 40.

The substrate 20 includes a mounting surface 20a that faces the holding member 10, and a back surface 20b that faces the back plate 30 and is positioned at the side opposite to the mounting surface 20a in the thickness direction of the substrate 20. The mounting surface 20a spreads in an X-direction and a Y-direction. The thickness direction of the substrate 20 is along a Z-direction crossing the X-direction and the Y-direction. The X-direction, the Y-direction, and the Z-direction cross each other and are, for example, orthogonal to each other. The substrate 20 is made of an insulative material. For example, a resin or a ceramic can be used as the material of the substrate 20.

The package component 40 includes a terminal placement surface 40a facing the mounting surface 20a of the substrate 20. The package component 40 is, for example, an optical transmission module. The semiconductor device 1 further includes an optical fiber 51 connected to the package component 40. A lens 52 is located at the connection part of the optical fiber 51 with the package component 40. For example, multiple optical fibers 51 can be connected to the package component 40. The optical fiber 51 extends in the Y-direction.

The package component 40 includes an optical element 42 that is optically connected with the optical fiber 51, and a semiconductor element 41 that is electrically connected with the optical element 42. The optical element 42 is a light-receiving element that converts an optical signal from the optical fiber 51 into an electrical signal and transmits the electrical signal to the semiconductor element 41. Or, the optical element 42 is a light-emitting element that converts an electrical signal from the semiconductor element 41 into an optical signal and transmits the optical signal to the optical fiber 51. The semiconductor element 41 is, for example, an IC (Integrated Circuit) chip.

The holding member 10 includes a component placement part 13 in which the package component 40 is located. The holding member 10 includes a first holding part 11 and a second holding part 12. For example, the component placement part 13 is formed as a through-part that extends in the thickness direction of the first holding part 11 (the Z-direction). In the X-direction and the Y-direction, the first holding part 11 surrounds the periphery of the package component 40 located in the component placement part 13. The optical fiber 51 passes through the first holding part 11 from the side of the first holding part 11 and is connected to the package component 40 located in the component placement part 13. For example, a metal or a ceramic can be used as the material of the first holding part 11. For example, a metal can be used as the material of the second holding part 12. The first holding part 11 and the second holding part 12 may be formed to have a continuous body.

The back plate 30 overlaps the back surface 20b of the substrate 20. For example, a metal or a ceramic can be used as the material of the back plate 30.

As shown in FIG. 1B, the semiconductor device 1 further includes multiple mounting pads 25 located at the mounting surface 20a of the substrate 20, and multiple package terminals located at the terminal placement surface 40a of the package component 40. The mounting pads 25 are electrically connected with interconnects formed in the substrate 20. The package terminals 45 are electrically connected with the semiconductor element 41.

The first holding part 11 is fixed with respect to the back plate 30. For example, a screw 71 extends through the first holding part 11 and the substrate 20 and is screwed into the back plate 30. The fastening force of the screw 71 holds the substrate between the first holding part 11 and the back plate 30. Any screw head shape, full- or half-threaded, etc., can be used as long as the screw 71 engages grooves cut into the opening or hole provided in the back plate 30. The screw 71 is strongly tightened to the back plate 30 by not grooving the holes of the first holding part 11 and the substrate 20 and by setting the inner diameters of the holes of the first holding part 11 and the substrate 20 to be larger than the exterior shape of the screw 71 measured at the screw thread tip.

The second holding part 12 is fixed with respect to the first holding part 11 and presses the package component 40 toward the substrate 20. For example, a screw 72 extends through the second holding part 12 and is screwed into the first holding part 11. The thickness of the package component 40 is greater than the thickness of the first holding part 11. Here, although the thickness refers to the Z-direction length, the thickness may be a thickness in a direction connecting the substrate 20 and the second holding part 12 at the shortest distance. In other words, an upper surface 40b of the package component 40 is positioned slightly above the upper surface of the first holding part 11 in the state in which the first holding part 11 and the package component 40 are placed on the mounting surface 20a of the substrate 20.

The lower surface of the second holding part 12 fixed to the first holding part 11 by, for example, the fastening force of the screw 72 contacts the upper surface 40b of the package component 40 and presses the package component 40 toward the substrate 20. Thereby, the package component 40 is held between the second holding part 12 and the substrate 20. As shown in FIG. 1B, the package terminal 45 is in direct contact with the mounting pad 25. The mounting position of the package component 40 on the substrate 20 is aligned by the component placement part 13 formed in the holding member 10. The package terminal 45 and the mounting pad 25 are aligned thereby.

According to the embodiment, the contact pressure between the package terminal 45 and the mounting pad 25 is ensured by directly pressing the package component 40 onto the substrate 20 by the holding member 10 without using a socket. A contact mechanism between the socket and the substrate 20 is unnecessary. The multiple package components 40 are mountable at a fine pitch on the substrate 20 without being constrained by the size of a socket. Because the package component 40 that is pressed onto the substrate 20 is supported by the back plate 30 directly under the package component 40, the package component 40 can be pressed onto the substrate 20 without the occurrence of warp even when the substrate 20 is thin or soft. By suppressing the warp of the substrate 20, high alignment accuracy between the package terminal 45 and the mounting pad 25 can be ensured.

The package component 40 can be detached from the component placement part 13 and replaced by detaching the second holding part 12 from the first holding part 11. For example, the second holding part 12 can be easily detached from the first holding part 11 by loosening and detaching the screw 72. Even when the second holding part 12 is detached from the first holding part 11 when replacing the package component 40, the positioning between the mounting pads 25 and the component placement part 13 formed in the first holding part 11 can be maintained without misalignment because the state in which the substrate 20 is held between the first holding part 11 and the back plate 30 is maintained. Accordingly, the high alignment accuracy between the package terminal 45 and the mounting pad can be ensured when the package component 40 is re-mounted on the substrate 20 by being located in the component placement part 13.

The semiconductor device 1 can further include a thermal via 61 extending through the substrate 20 in the thickness direction. The heat of the package component 40 can be dissipated by the thermal via 61 and the back plate 30.

### Second Embodiment

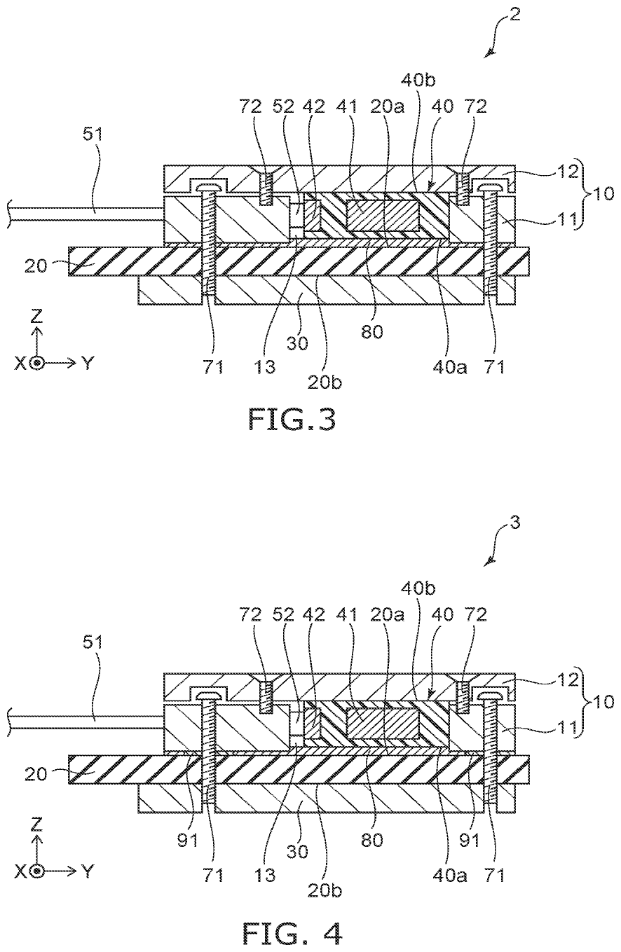

A semiconductor device 2 of a second embodiment shown in FIG. 3 further includes an anisotropic conductive sheet 80 in addition to the configuration of the semiconductor device 1 of the first embodiment described above.

The anisotropic conductive sheet 80 is located between the terminal placement surface 40a of the package component 40 and the mounting surface 20a of the substrate 20. The anisotropic conductive sheet 80 is held between the terminal placement surface 40a and the mounting surface 20a by the package component 40 being pressed onto the substrate 20 by the second holding part 12. Thereby, the package terminals 45 located at the terminal placement surface 40a and the mounting pads 25 located at the mounting surface 20a are pressed onto the anisotropic conductive sheet 80; and the package terminals 45 are electrically connected with the mounting pads 25 via the anisotropic conductive sheet 80.

The anisotropic conductive sheet 80 includes, for example, an insulating member such as a silicone resin or the like, and multiple conductive core wires providing a connection extending between the upper and lower surfaces of the insulating member. By obliquely forming the conductive core wires with respect to the electrical connection direction of the package terminal 45 and the mounting pad 25 (the Z-direction in FIGS. 1A and 1B), elastic deformation due to the pressing of the package terminal 45 and the mounting pad 25 toward the anisotropic conductive sheet 80 can be allowed, and the electrical connectability can be maintained.

The anisotropic conductive sheet 80 also is located between the first holding part 11 and the substrate 20. For example, the anisotropic conductive sheet 80 is compressed between the first holding part 11 and the substrate 20 by the substrate 20 being clamped between the first holding part 11 and the back plate 30 by the fastening force of the screw 71. Thereby, the thickness of the anisotropic conductive sheet 80 between the first holding part 11 and the substrate 20 is less than the thickness of the anisotropic conductive sheet 80 between the package component 40 and the substrate 20. In such a case, the upper surface 40b of the package component 40 can be positioned higher than the upper surface of the first holding part 11; and the upper surface 40b of the package component 40 can be pressed toward the substrate 20 by the lower surface of the second holding part 12 without the need to make the thickness of the package component 40 greater than the thickness of the first holding part 11.

### Third Embodiment

A semiconductor device 3 of a third embodiment shown in FIG. 4 further includes a spacer 91 located between the first holding part 11 and the substrate 20 in addition to the configuration of the semiconductor device 2 of the second embodiment.

The spacer 91 is, for example, a ring-shaped metal member. The screw 71 extends through the ring-shaped spacer 91. The spacer 91 is clamped between the first holding part 11 and the substrate 20 at the periphery of the screw 71. The spacer 91 can maintain the distance between the substrate 20 and the lower surface of the first holding part 11 at a constant distance. The step between the upper surface of the first holding part 11 and the upper surface of the upper surface 40b of the package component 40 can be adjusted thereby, and the pressure on the package component 40 from the second holding part 12 can be adjusted.

### Fourth Embodiment

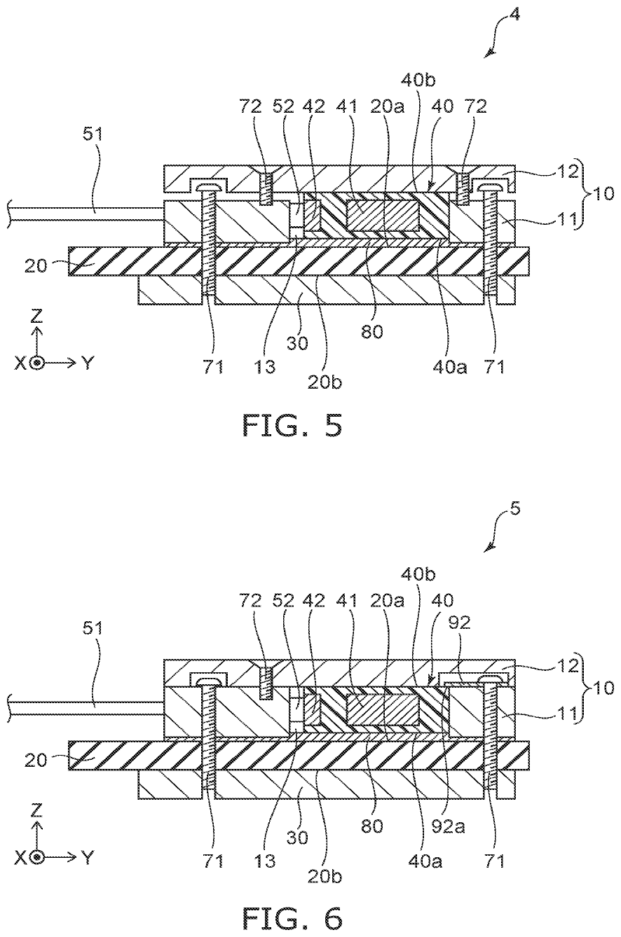

By setting the thickness of the first holding part 11 to be less than the thickness of the package component 40 as in a semiconductor device 4 of a fourth embodiment shown in FIG. 5, the pressure of the lower surface of the second holding part 12 pressing the upper surface 40b of the package component 40 toward the substrate 20 can be increased.

### Fifth Embodiment

A semiconductor device 5 of a fifth embodiment shown in FIG. 6 includes a temporary holding plate 92 located at the upper surface of the first holding part 11. For example, the temporary holding plate 92 is fixed to the upper surface of the first holding part 11 by the screw 71. A portion 92a of the temporary holding plate 92 is positioned above the component placement part 13. The temporary holding plate 92 may be a continuous body with the first holding part 11.

When placing the package component 40 in the component placement part 13, before the package component 40 is pressed onto the substrate 20 by the second holding part 12, the package component 40 can be temporarily fixed in the component placement part 13 by clamping a portion of the package component 40 between the substrate 20 and the portion 92a of the temporary holding plate 92. By temporarily fixing the package component 40, the package component 40 can be prevented from lifting in the Z-direction. Misalignment of the package component 40 due to, for example, pulling by the optical fiber 51, etc., can be suppressed thereby when mounting the second holding part 12 to the first holding part 11. As a result, high alignment accuracy between the package terminal 45 and the mounting pad 25 can be ensured.

### Sixth Embodiment

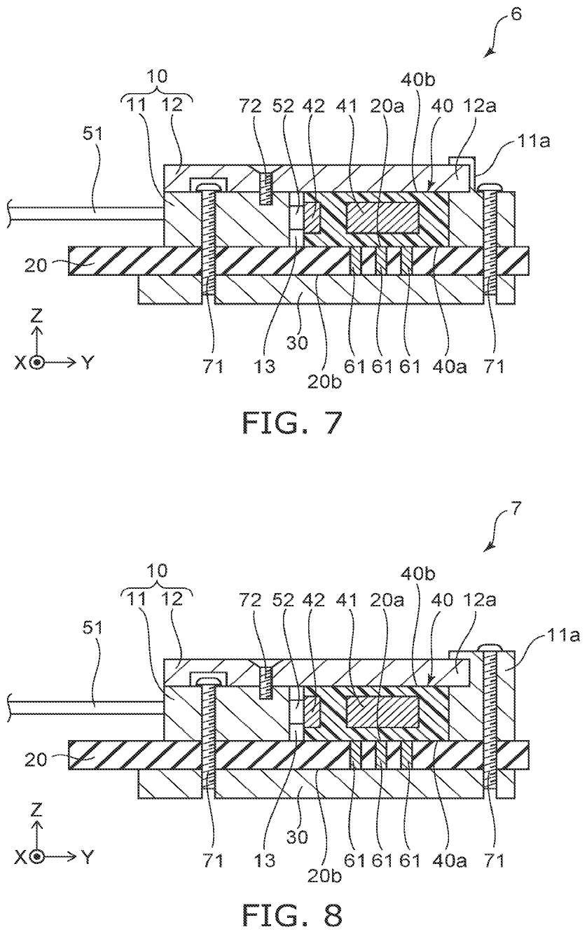

Semiconductor devices 6 to 8 of a sixth embodiment shown in FIGS. 7 to 9 include a holding structure 11a holding the second holding part 12 located at the upper surface of the first holding part 11. A portion of the second holding part 12 is inserted into a portion of the first holding part 11 by using the holding structure 11a. The holding structure 11a is positioned above the component placement part 13. The holding structure 11a continuously includes a part that extends in the Y-direction, and a part that extends in the Z-direction with a length not less than the thickness of the second holding part 12. One end part 12a of the second holding part 12 in the Y-direction is positioned between the first holding part 11 and the part of the holding structure 11a extending in the Y-direction. The one end part 12a of the second holding part 12 is fixed in contact with the first holding part 11 by inserting the side of the second holding part 12 at the end part 12a side between the first holding part 11 and the holding structure 11a, and in this state, the vicinity of the other end part of the second holding part 12 in the Y-direction is fastened to the first holding part 11 by the screw 72. Thereby, the package component 40 is held between the second holding part 12 and the substrate 20. By using the holding structure 11a, the number of screws 72 for pressing the package component 40 toward the substrate 20 can be reduced, and the number of tasks when replacing the screws 72 can be reduced.

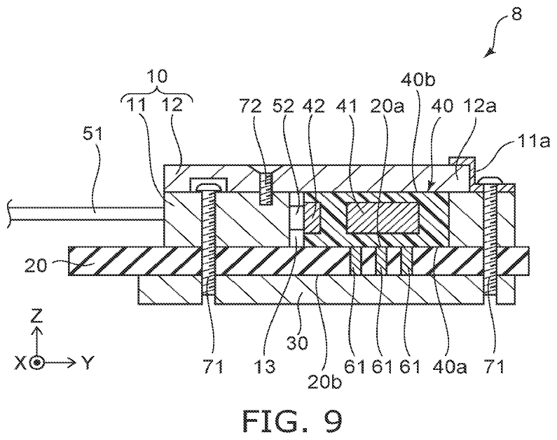

The holding structure 11a may have a shape in which a portion of the first holding part 11 protrudes as in FIG. 7. The Z-direction thickness of the first holding part 11 may be increased as in FIG. 8. The strength of the protruding part can be increased by using the structure of FIG. 8. As shown in FIG. 9, the holding structure 11a may be a member separate from the first holding part 11, and may be fixed to the upper surface of the first holding part 11 by, for example, the screw 71. For example, the holding structure 11a shown in FIG. 9 can be realized by using a continuous structure including a part that extends in the Y-direction and is fixed by the screw 71, a part that extends in the Z-direction with a length not less than the thickness of the second holding part 12, and a part that extends in the Y-direction and overlaps the second holding part 12 in the Z-direction. Thereby, only the holding structure 11a can be modified according to the thickness of the second holding part 12 without the need to change the entire first holding part 11. Also, the holding structure 11a is easily replaced when deformed.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor device, comprising:
a holding member including a component placement part;
a back plate;
a substrate including
a mounting surface facing the holding member, and
a back surface positioned at a side opposite to the mounting surface, the back surface facing the back plate;
a plurality of mounting pads located at the mounting surface;
a package component including a terminal placement surface, the terminal placement surface facing the mounting surface; and
a plurality of package terminals located at the terminal placement surface,
the substrate being held between the holding member and the back plate,
the package component being located in the component placement part, and held between the holding member and the substrate,
the package terminals being in direct contact with the mounting pads.

2. The device according to claim 1, further comprising:
a thermal via extending through the substrate.

3. The device according to claim 1, wherein
the holding member includes:
a first holding part fixed with respect to the back plate; and
a second holding part fixed with respect to the first holding part,
the second holding part pressing the package component toward the substrate.

4. The device according to claim 3, wherein
a thickness of the first holding part is less than a thickness of the package component.

5. The device according to claim 3, wherein
the second holding part is fixed to the first holding part by a portion of the second holding part being inserted into a portion of the first holding part.

6. The device according to claim 1, further comprising:
an optical fiber connected to the package component,
the package component including
an optical element optically connected with the optical fiber, and
a semiconductor element electrically connected with the optical element.

7. A semiconductor device, comprising:
a holding member including a component placement part;
a back plate;
a substrate including
a mounting surface facing the holding member, and
a back surface positioned at a side opposite to the mounting surface, the back surface facing the back plate;
a plurality of mounting pads located at the mounting surface;
a package component including a terminal placement surface, the terminal placement surface facing the mounting surface;
a plurality of package terminals located at the terminal placement surface; and
an anisotropic conductive sheet located between the terminal placement surface of the package component and the mounting surface of the substrate,
the substrate being held between the holding member and the back plate,
the package component being located in the component placement part and held between the holding member and the substrate,
the package terminal being electrically connected with the mounting pad via the anisotropic conductive sheet.

8. The device according to claim 7, wherein
the anisotropic conductive sheet also is located between the holding member and the substrate, and
a thickness of the anisotropic conductive sheet between the holding member and the substrate is less than a thickness of the anisotropic conductive sheet between the package component and the substrate.

9. The device according to claim 7, further comprising:
a spacer located between the holding member and the substrate.

10. The device according to claim 7, further comprising:
a thermal via extending through the substrate.

11. The device according to claim 7, wherein
the holding member includes:
a first holding part fixed with respect to the back plate; and
a second holding part fixed with respect to the first holding part,
the second holding part pressing the package component toward the substrate.

12. The device according to claim 11, wherein
a thickness of the first holding part is less than a thickness of the package component.

13. The device according to claim 11, wherein
the second holding part is fixed to the first holding part by a portion of the second holding part being inserted into a portion of the first holding part.

14. The device according to claim 7, further comprising:
an optical fiber connected to the package component,
the package component including
an optical element optically connected with the optical fiber, and
a semiconductor element electrically connected with the optical element.
